(19) United States
(12) Patent Application Publication
(10) Pub. No.: US 2025/0227985 A1
(43) Pub. Date: Jul. 10, 2025

(54) GATE REGULATOR CIRCUIT FOR GaN POWER SWITCH

(71) Applicant: GaNPower International Inc., Vancouver (CA)

(72) Inventors: Zhanming LI, West Vancouver (CA); Youyi ZHAO, Vancouver (CA)

(21) Appl. No.: 18/908,178

(22) Filed: Oct. 7, 2024

Related U.S. Application Data
(60) Provisional application No. 63/617,541, filed on Jan. 4, 2024.

(51) Int. Cl. H01L 27/06; H03K 17/687

(52) U.S. Cl. CPC H10D 84/811; H03K 17/687

(57) ABSTRACT

An integrated circuit includes a main switch, wherein the main switch comprises a first high electron mobility transistor (HEMT). The integrated circuit includes a subcircuit comprising a plurality of second HEMTs, a gate of the main switch is electrically connected to the subcircuit, each of the plurality of second HEMTs is drain-to-gate connected. The integrated circuit includes a third HEMT electrically connected to the gate of the main switch, wherein the third HEMT is drain-to-gate connected, and a drain of the third HEMT is electrically connected to a source of the main switch. The integrated circuit includes a fourth HEMT electrically connected to the gate of the main switch, the fourth HEMT is drain-to-gate connected. The integrated circuit includes a fifth HEMT electrically connected to the gate of the main switch, wherein the fifth HEMT is source-to-gate connected, and the fourth HEMT is connected in parallel with the fifth HEMT.

### PRIORITY CLAIM AND CROSS-REFERENCE

This application claims priority to Provisional Application 63/617,541, filed Jan. 4, 2024, the entire contents of which are hereby incorporated by reference.

### BACKGROUND

Gallium nitride (GaN) field effect transistors (FET) discrete power devices are known to be different than silicon metal-oxide semiconductor FET (Si MOSFET) and silicon carbide (SiC) MOSFET. Differences between GaNFET and Si MOSFET or SiC MOSFET include gate driving voltages and threshold voltages (Vgth). MOSFET gate threshold voltage Vgth typically is around 2 volts (V) to 5V while the gate driving voltage typically ranges from −20 V to +20V. In contrast, GaNFETs have a low threshold voltage Vgth, typically 1V to 2V and the gate driving voltage ranging from −3 V to +7 V. The smaller Vgth increases a risk that the GaNFET will falsely turn on due to low gate voltage noise. A smaller gate driving range also increases a risk of damage if a system generates a voltage exceeding the −3 V to +7V range. This invention describes a circuit design that regulates the input control voltage range common for MOSFET into one that suits GaNFET. The gate threshold voltage is also increased so that the performance of GaNFET is similar to MOSFET for better robustness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a gate regulator for a gallium nitride integrated circuit (GaN-IC), in accordance with some approaches.

FIG. 2A is a schematic diagram of a GaN-IC usable for direct current (DC) testing, in accordance with some embodiments.

FIG. 2B is a graph of an output of the GaN-IC of FIG. 2(a), in accordance with some embodiments.

FIG. 3A is a schematic diagram of a GaN-IC usable for dynamic switching testing, in accordance with some embodiments.

FIG. 3B is a graph of an output of the GaN-IC of FIG. 3(a), in accordance with some embodiments.

FIG. 4A is a top view of a layout of a GaN-IC, in accordance with some embodiments.

FIG. 4B is a top view of a layout of a portion of the GaN-IC of FIG. 4(a), in accordance with some embodiments.

FIG. 5A is a schematic diagram of a GaN-IC usable for direct current (DC) testing, in accordance with some embodiments.

FIG. 5B is a graph of an output of the GaN-IC of FIG. 5(a), in accordance with some embodiments.

FIG. 6 is a top view of a layout of a portion of the GaN-IC, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following descriptions, all depletion mode (DMODE) FETs with G and S connected are replaceable with a two-dimensional electron gas (2DEG) resistor of similar size.

Most enhanced mode (E-mode) GaNFETs have a designed maximum gate voltage (Vg) of −3 volts (V) to +7V. This gate voltage is significantly lower than most MOSFETs or silicon carbide (SiC) MOSFETs which are designed to have a wider gate driving range of −20 V to +20 V. Embodiments of this description relate to a circuit design that regulates the input control voltage range common for metal oxide semiconductor field effect transistor (MOSFET) into a voltage range usable for a gallium nitride field effect transistor (GaNFET). The gate threshold voltage is also increased so that the performance of GaNFET is similar to MOSFET for better robustness. The description below focuses on gallium nitride GaN type FETs. However, one of ordinary skill in the art would understand that other types of high electron mobility transistors (HEMTs) are within the scope of this description.

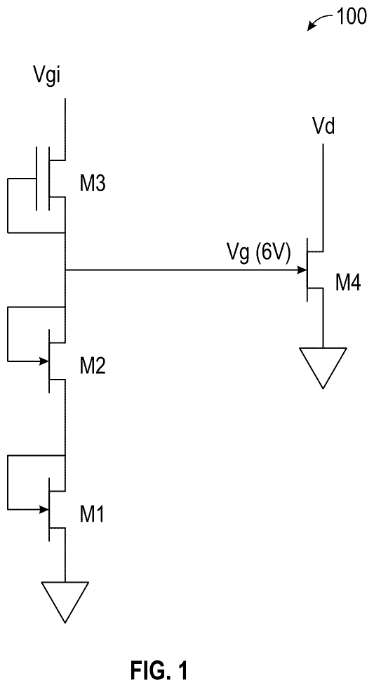

FIG. 1 is a schematic diagram of a gate regulator 100 for a gallium nitride integrated circuit (GaN-IC), in accordance with some approaches. The gate regulator 100 includes a GaN transistor M1, a GaN transistor M2 and a GaN transistor M3 connected between an input voltage Vgi and a ground voltage. The gate regulator 100 further includes a GaNFET M4 connected between a source voltage Vd and the ground voltage. A gate of the GaNFET M4 is connected to a source/drain (S/D) region between the GaN transistor M2 and the GaN transistor M3. The gate regulator is usable to clamp an input voltage Vgi and enhance the driving range of transistor GaNFET M4. However, the gate regulator 100 is incapable of changing a threshold voltage Vgth of the GaNFET M4. In some embodiments, the GaN transistor M1 is a depletion mode (DMODE) HEMT.

Embodiments of this description described below help to increase the threshold voltage Vgth, and to increase the gate driving range; as well as maintaining fast switching dynamic capability of the GaNFET.

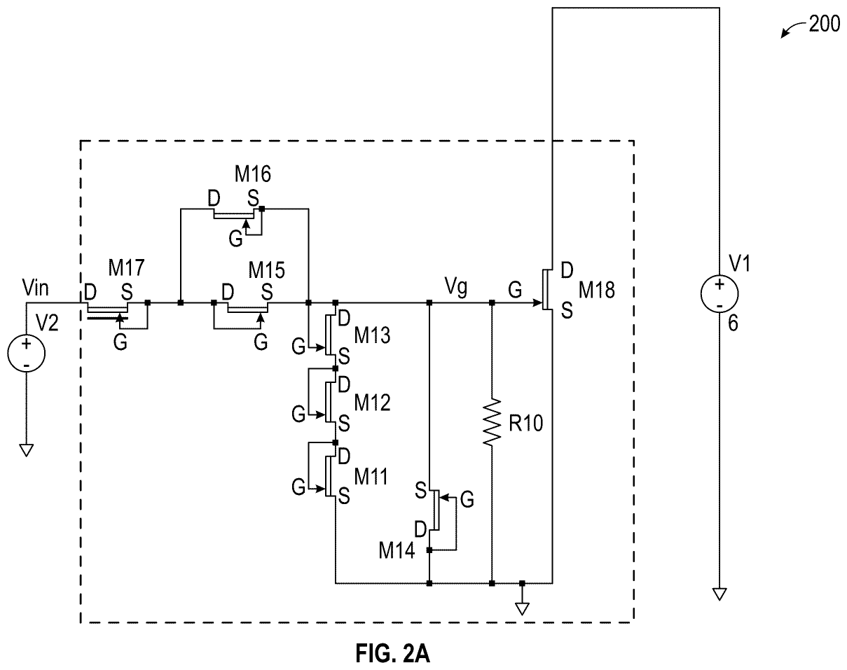

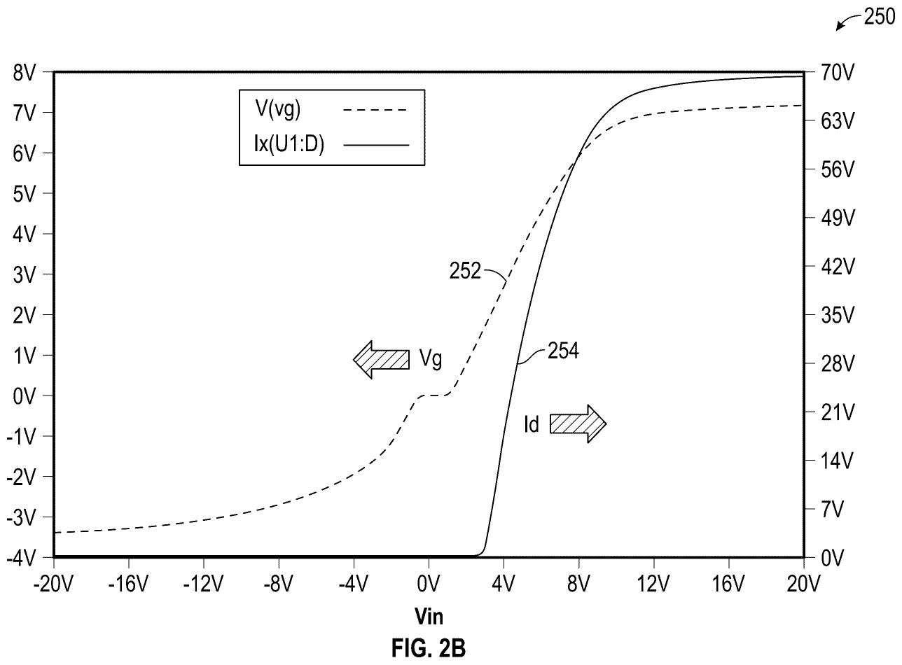

FIG. 2A is a schematic diagram of a GaN-IC 200 usable for direct current (DC) testing, in accordance with some embodiments. The GaN-IC 200 includes a plurality of FETs M11-M18 and a resistor R10. One of ordinary skill in the art would understand that modifications to this arrangement are within the scope of this description and that other passive components, such as resistors, are able to be included in the GaN-IC 200. The DMODE FET M17 is configured to receive an input voltage (Vin). The FET M18 functions as a main switch and is configured to produce an output voltage (V1). The GaN-IC 200 is configured to control the threshold voltage Vgth of the main switch M18 and to increase a gate driving range of the main switch M18. As a result, the GaN-IC 200 is capable of faster switching than other approaches that utilize GaN transistors.

The GaN-IC 200 includes low voltage FETs M11, M12 and M13. The low voltage FETs M11, M12 and M13 are connected in parallel with a main switch M18 of the GaN-IC 200. The low voltage FETs M11, M12 and M13 help to regulate a voltage (Vg) at a gate of the main switch M18. In some embodiments, the low FETs M11, M12 and M13 regulate the voltage Vg to be approximately 6 volts (V) in response to the input voltage Vin being logically high. Each of the FETs M11 to M13 are drain-to-gate connected.

The GaN-IC 200 further includes a FET M14 connected in parallel with the low voltage FETs M11, M12 and M13. The FET M14 provides a voltage clamp in a negative input voltage, i.e., the FET M4 is connected in such a way that the FET M14 blocks positive voltage while allowing negative current to pass. The GaN-IC 200 further includes a resistor R10 connected in parallel with the FET M14. In some embodiments, the FETs M11 to M14 are called a sub-circuit. The FET M14 is drain-to-gate connected.

The GaN-IC 200 further includes a FET M15 connected in series with the main switch M18. The FET M15 is able to increase a threshold voltage (Vgth) of the FET M15 itself. The FET M15 is still capable of blocking a discharging current when the input voltage Vin is logically low. The FET M15 is drain-to-gate connected

The GaN-IC 200 further includes a FET M16 connected in parallel with the FET M15. The FET M16 provides a discharge path such that the FET M16 blocks a charging current but allows a discharging current to flow. The FET M16 is source-to-gate connected.

The GaN-IC 200 further includes a FET M17 connected in a Dmode. The FET M17 is usable as a variable resistor where a resistance of the FET M17 increases as the input voltage Vin increases. The variable resistance effectively clamps the voltage from the logically high voltage to a lower voltage for driving the main switch M18. In some embodiments, the lower voltage is less than approximately 7 V. The FET M17 is source-to-gate connected. In some embodiments, Dmode M17 is replaced by a 2DEG resistor of similar size as the replaced M17.

In some embodiments, the GaN-IC 200 has a breakdown voltage rating ranging from 20V to 100V. In some embodiments, the main switch M18 has a breakdown voltage rating ranging from 40V to 1500V.

FIG. 2B is a graph 250 of an output of the GaN-IC of FIG. 2A, in accordance with some embodiments. The graph 250 provides simulation results for a direct current (DC) simulation results of the GaN-IC 200 (FIG. 2A). The graph 250 includes a first plot 252 which indicates a gate voltage (Vg) of the main switch M18 (FIG. 2A) versus the input voltage Vin. The graph 250 further includes a second plot 254 which indicates a current (Id) through the main switch M18 versus the input voltage Vin.

The second plot 254 indicates that the main switch M18 (FIG. 2A) becomes conductive at an input voltage Vin of about 2.8V. This 2.8V is considered a threshold voltage for the GaN-IC 200 (FIG. 2A). The 2.8V threshold voltage is an increase from a threshold voltage of about 1.5V in other approaches that include GaN components. The 2.8V threshold voltage is more consistent with non-GaN components in an IC. Therefore, having the structure of GaN-IC 200 helps with integration of the GaN-IC 200 into devices that include both GaN components and non-GaN components.

The first plot 252 indicates that the clamping effect on the gate voltage Vg ranges from about −3 V to about 7 V. A slope of the first plot 252 and a slope of the second plot 254 further indicate an effective gate resistance of the main switch M18 (FIG. 2A) is minimal between input voltage Vin from about 3 V to about 6 V. This minimal resistance helps to enable effective current sinking and sourcing for the main switch M18 (FIG. 2A).

Overall, the graph 250 provides evidence that the GaN-IC 200 has better performance than other approaches that include GaN components. The graph 250 indicates that the GaN-IC 200 (FIG. 2A) provides improved integration into circuit designs and improved performance in comparison with other approaches.

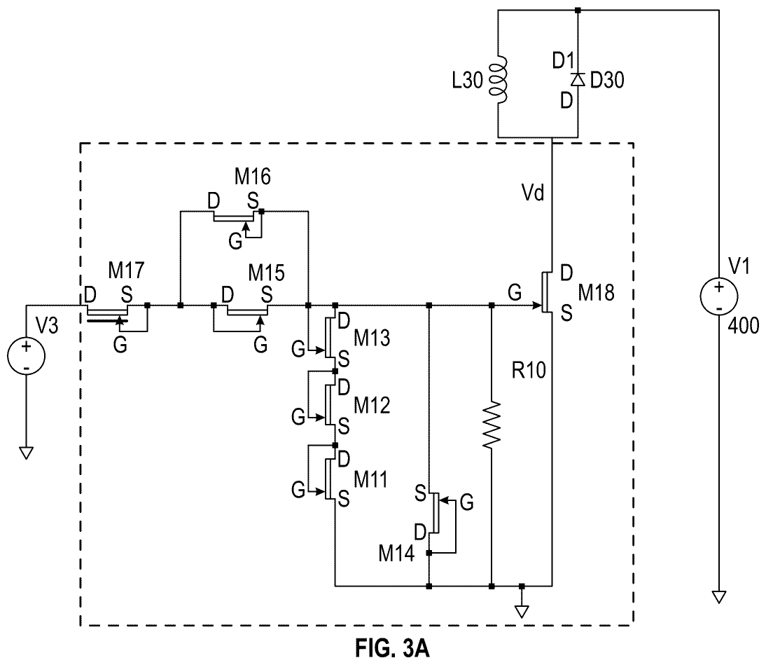

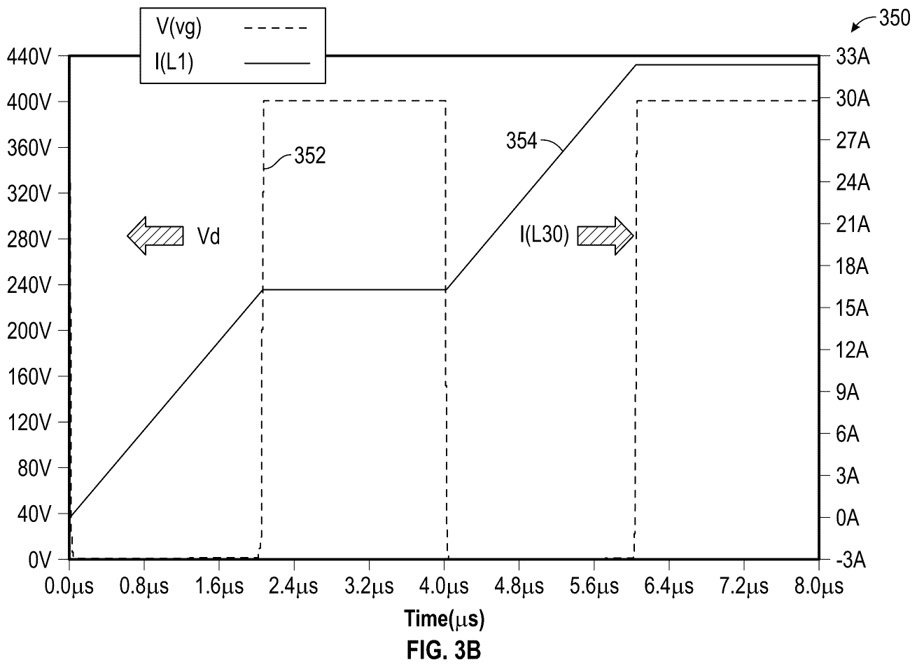

FIG. 3A is a schematic diagram of a GaN-IC 300 usable for dynamic switch testing, in accordance with some embodiments. Some components of the GaN-IC 300 are similar to components of the GaN-IC 200 (FIG. 2A). For the sake of brevity, components discussed above with respect to GaN-IC 200 (FIG. 2A) are not discussed here in detail for GaN-IC 300. In comparison with GaN-IC 200 (FIG. 2A), the GaN-IC 300 includes an inductor L30 and a diode D30 connected to a terminal of the main switch M18. The inductor L30 and the diode D30 are between the main switch M18 and output voltage V1. The inductor L30 is connected in parallel with the diode D30. The inclusion of the inductor L30 and the diode D30 facilitate testing of dynamic behavior of the GaN-IC 300. In some embodiments, the GaN-IC 300 has a breakdown voltage rating ranging from 20V to 100V. In some embodiments, the main switch M18 has a breakdown voltage rating ranging from 40V to 1500V.

FIG. 3B is a graph 350 of an output of the GaN-IC 300 of FIG. 3A, in accordance with some embodiments. The graph 350 includes a first plot 352 of a voltage Vd at a terminal of the main switch M18 connected to the inductor L30 (FIG. 3A) versus time. The graph 350 further includes a second plot 354 of a current across the inductor L30 (FIG. 3A) versus time. The first plot 352 indicates time periods where the main switch M18 (FIG. 3A) is in a conductive state. That is, when the first plot 352 indicates a voltage greater than 0 V, the main switch M18 (FIG. 3A) is in a conductive state; and when the first plot 352 indicates a voltage of 0V, the main switch M18 (FIG. 3A) is in a non-conductive state. During a conductive state of the main switch M18 (FIG. 3A), a current across the inductor L30 (FIG. 3A) remains constant. During a non-conductive state of the main switch M18 (FIG. 3A) the current across the inductor L30 (FIG. 3A) increases. The first plot 352 and the second plot 354 demonstrate that both turn-on and turn-off behavior of the main switch M18 (FIG. 3A) are similar to non-GaN components in an IC with no significant slow down or delay caused by the use of the inductor L30 and diode D30 (FIG. 3A). The results in FIG. 3B clearly indicate fast charging and discharging of the main power switch and provides evidence that the embodiment does not slow down the switching of main power switch.

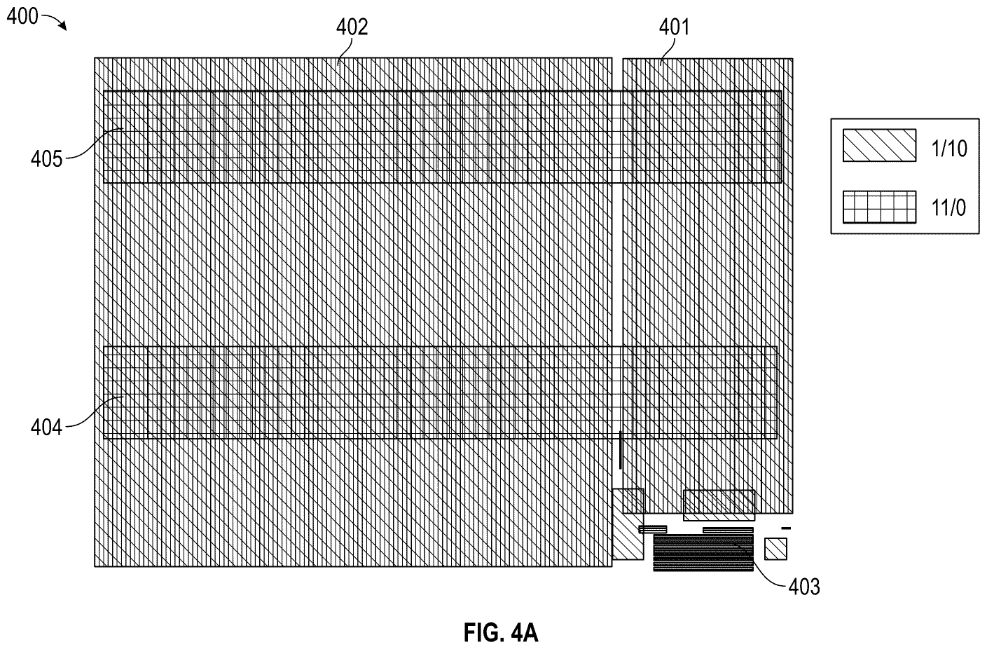

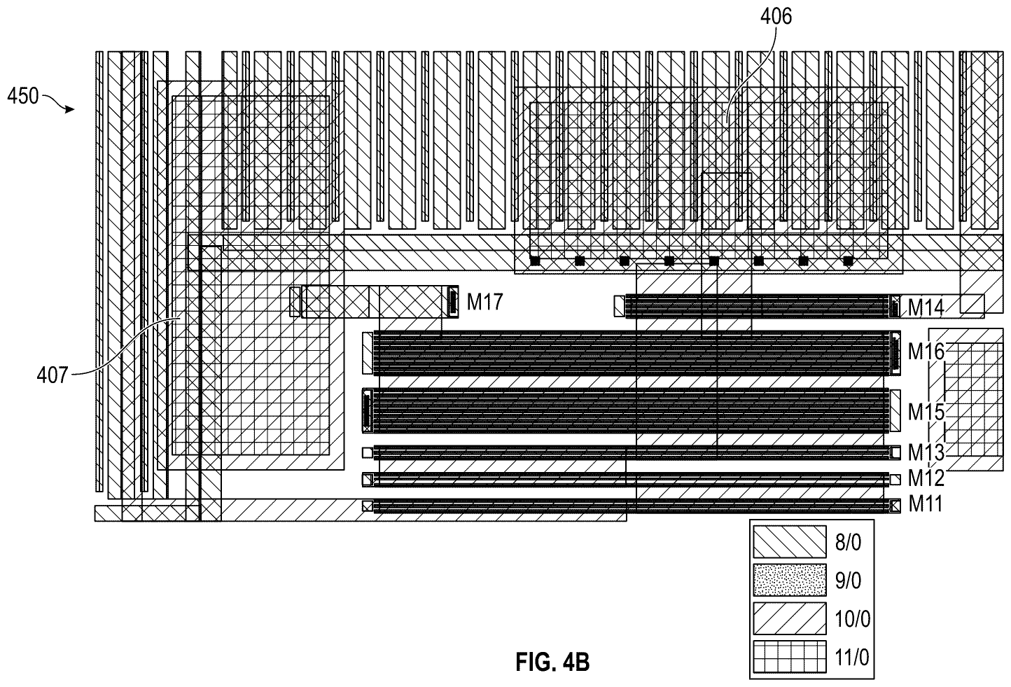

FIG. 4A is a top view of a layout 400 of a GaN-IC, in accordance with some embodiments. In some embodiments, the layout 400 of the GaN-IC is usable to form the GaN-IC 200 (FIG. 2A) or the GaN-IC 300 (FIG. 3A). In some embodiments, the layout 400 of the GaN-IC is usable to form a device different from the GaN-IC 200 (FIG. 2A) or the GaN-IC 300 (FIG. 3A). The layout 400 of the GaN-IC includes more than just a GaN-IC and indicates how the GaN-IC part is located with respect to other components in an IC that are not GaN based.

The layout 400 includes a first layer, layer 1/0, and a second layer, layer 11/0. The first layer 1/0 indicates an active area of a wafer. The second layer 11/0 indicates a contact pad opening. The layout 400 further includes finger pair areas that have different size fingers. The region 401 includes finger pairs having a first size. The region 402 includes finger pairs having a second size, greater than the first size. The region 403 includes the GaN-IC, e.g., the GaN-IC 200 (FIG. 2A) or the GaN-IC 300 (FIG. 3A). In order to reduce electrical interference, the region 403 is positioned close to a source pad 404. The layout 400 further includes a drain pad 405. The source pad 404 and the drain pad 405 extend continuously across the first region 401 and the second region 402. The source pad 404 is between the region 403 and the drain pad 405.

FIG. 4B is a top view of a layout 450 of a portion of the GaN-IC of FIG. 4A, in accordance with some embodiments. The layout 450 is focused primarily on the region 403 (FIG. 4A). In some embodiments, the layout 450 is a layout of the GaN-IC 200 (FIG. 2A), the GaN-IC 300 (FIG. 3A) or another suitable GaN-IC.

The layout 450 includes a layer 8/0, corresponding to a metal 1 layer. The layout 450 includes a layer 10/0, corresponding to a metal 2 layer. The layout 450 further includes a layer 9/0 corresponding to a via connecting metal 1 layer 8/0 and metal 2 layer 10/0. As with the layout 400 (FIG. 4A), the layer 11/0 corresponds to the contact pad opening.

M11 to M17 correspond to FETs in the GaN-IC 200 (FIG. 2A) or the GaN-IC 300 (FIG. 3A). The region 406 is a contact pad opening for the metal 2 layer 10/0 for a gate contact of the main switch M18 (FIGS. 2A and 3A). Region 407 is an input of the GaN-IC, e.g., GaN-IC 200 (FIG. 2A) or GaN-IC 300 (FIG. 3A), and is configured to carry a voltage ranging from −20 V to 20 V. The FETs M11 to M17 are arranged in a parallel manner having a same length in order to help minimize space in the overall IC design. One of ordinary skill in the art would understand that other arrangements of the FETs M11 to M17 are within the scope of this description. For example, in some embodiments, at least one of the FETs M11 to M17 is not parallel to at least one other of the FETs M11 to M17. Further, in some embodiments, at least one of the FETs M11-M17 has a different length from at least one other of the FETs M11 to M17.

The FETs M11 to M13 are in parallel with source and drain sides flipped to facilitate electrical connections to connect a drain of FET M11 to a source of FET M12; and a drain of FET M12 to a source of FET M13. FETs M15 and M16 control the charging in both directions and the size of the FETs M15 and M16 are adjustable for different designed based on sinking and sourcing specifications.

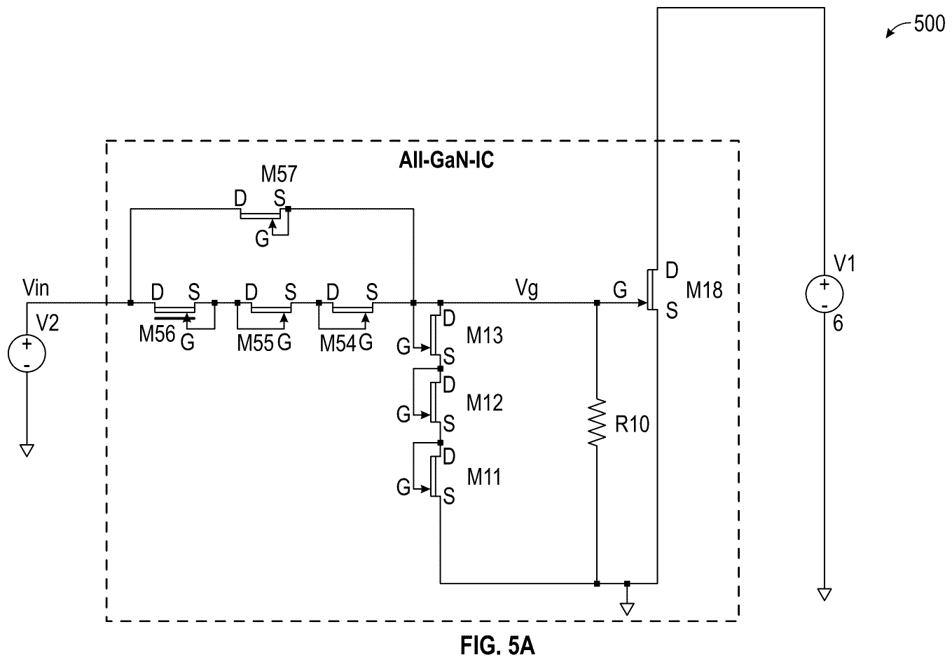

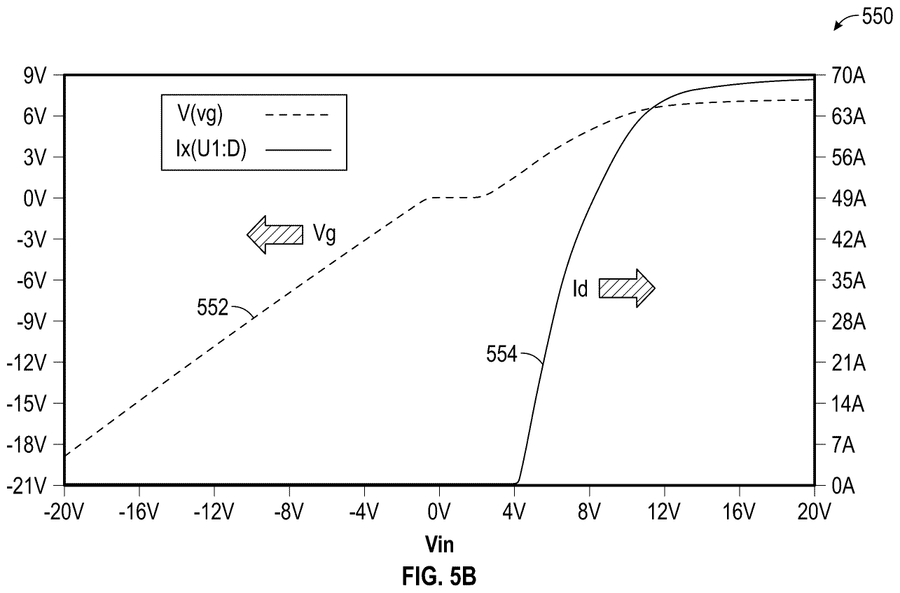

FIG. 5A is a schematic diagram of a GaN-IC 500 usable for direct current (DC) testing, in accordance with some embodiments. Some components of the GaN-IC 500 are similar to components of the GaN-IC 200 (FIG. 2A). For the sake of brevity, components discussed above with respect to GaN-IC 200 (FIG. 2A) are not discussed here in detail for GaN-IC 500. In comparison with GaN-IC 200 (FIG. 2A), the GaN-IC 500 includes FETs M54 to M57 instead of FETs M14 to M17.

The GaN-IC 500 utilizes more FETs to increase the threshold voltage Vgth of the main switch M18. FETs M54 and M55 are both used to increase the Vgth by two times the normally off Vgth of a single FET, such as the arrangement in GaN-IC 200 (FIG. 2A). Therefore, if the regular FET Vgth for the main switch M18 is 1.3V, using the FETs M54 and M55 will boost Vgth for the main switch M18 to 4V. The 4V threshold voltage Vgth is similar to silicon MOSFET and SiC components. Due to the use of more FETs for input voltage, a path through FET M57 is utilized to release the discharging gate current while turning off. In GaN-IC 500, the discharging current is directly discharged to the input point Vin. The Dmode FET M56 has a similar functionality as the FET M17 from the GaN-IC 200 (FIG. 2A). The FETs M54 and M55 are drain-to-gate connected. The FETs M56 and M57 are source-to-gate connected.

In some embodiments, the GaN-IC 500 has a breakdown voltage rating ranging from 20V to 100V. In some embodiments, the main switch M18 has a breakdown voltage rating ranging from 40V to 1500V.

FIG. 5B is a graph 550 of an output of the GaN-IC 500 of FIG. 5A, in accordance with some embodiments. The graph 550 provides simulation results for a direct current (DC) simulation results of the GaN-IC 500 (FIG. 5A). The graph 550 includes a first plot 552 which indicates a gate voltage (Vg) of the main switch M18 (FIG. 5A) versus the input voltage Vin. The graph 550 further includes a second plot 554 which indicates a current (Id) through the main switch M18 versus the input voltage Vin.

The second plot 554 indicates that the main switch M18 (FIG. 5A) becomes conductive at an input voltage Vin of about 4V. This 4V is considered a threshold voltage for the GaN-IC 500 (Figure AA). The 4V threshold voltage is an increase from a threshold voltage of about 1.5V or 2.8V in other approaches that include GaN components. The 4V threshold voltage is more consistent with non-GaN components in an IC. Therefore, having the structure of GaN-IC 500 helps with integration of the GaN-IC 500 into devices that include both GaN components and non-GaN components.

The first plot 552 indicates that the clamping effect on the gate voltage Vg of less than about 7 V. A slope of the first plot 552 and a slope of the second plot 554 further indicate an effective gate resistance of the main switch M18 (FIG. 5A) is minimal between input voltage Vin from about 3 V to about 9 V. This minimal resistance helps to enable effective current sinking and sourcing for the main switch M18 (FIG. 5A).

Overall, the graph 550 provides evidence that the GaN-IC 500 has better performance than other approaches that include GaN components. The graph 550 indicates that the GaN-IC 500 (FIG. 5A) provides improved integration into circuit designs and improved performance in comparison with other approaches.

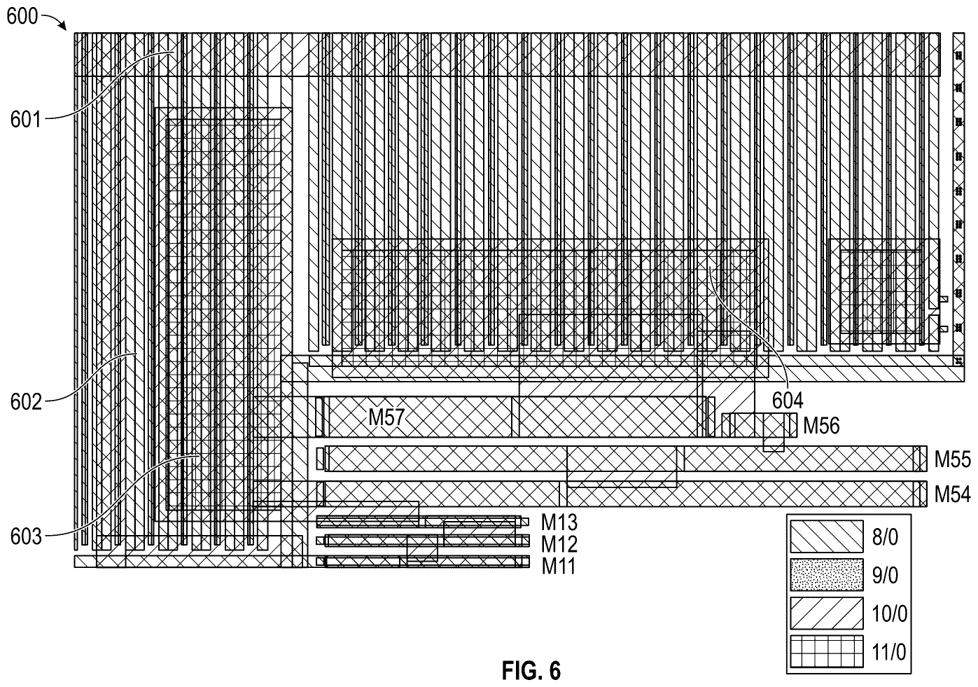

FIG. 6 is a top view of a layout 600 of a portion of the GaN-IC, in accordance with some embodiments. In some embodiments, the layout 600 of the GaN-IC is usable to form the GaN-IC 500 (FIG. 5A). In some embodiments, the layout 600 of the GaN-IC is usable to form a device different from the GaN-IC 500 (FIG. 5A). The layout 600 focuses on a portion of an IC including the GaN-IC. In some embodiments, the layout 600 is usable as region 403 of the layout 400 (FIG. 4A).

The layout 600 includes a layer 8/0, corresponding to a metal 1 layer. The layout 600 includes a layer 10/0, corresponding to a metal 2 layer. The layout 600 further includes a layer 9/0 corresponding to a via connecting metal 1 layer 8/0 and metal 2 layer 10/0. As with the layout 400 (FIG. 4A), the layer 11/0 corresponds to the contact pad opening.

M11 to M13 correspond to FETs in the GaN-IC 500 (FIG. 5A). M54 to M57 correspond to FETs in the GaN-IC 500 (FIG. 5A). In comparison with the FETs M11 to M13, the FETs M54 to M57 have an increased size in order to permit higher voltages and currents to flow through the FETs M54 to M57. The region 601 is a contact open in the metal 2 layer 10/0 for a source contact pad. The region 602 is a conduction path in the metal 2 layer 10/0 for a conductive line electrically connected to the source contact pad. The region 604 is a contact pad opening for the metal 2 layer 10/0 for a gate contact of the main switch M18 (FIG. 5A). Region 604 is an input of the GaN-IC, e.g., GaN-IC 500 (FIG. 5A), and is configured to carry a voltage ranging from −20 V to 20 V. The FETs M11 to M13 and M54 to M57 are arranged in a parallel manner to help minimize space in the overall IC design. One of ordinary skill in the art would understand that other arrangements of the FETs M11 to M13 and M544 to M57 are within the scope of this description. For example, in some embodiments, at least one of the FETs M11 to M13 or M54 to M57 is not parallel to at least one other of the FETs M11 to M13 or M54 to M57.

The FETs M11 to M13 are in parallel with source and drain sides flipped to facilitate electrical connections to connect a drain of FET M11 to a source of FET M12; and a drain of FET M12 to a source of FET M13. FETs M54 to M57 control the charging in both directions and the size of the FETs M54 to M57 are adjustable for different designed based on sinking and sourcing specifications.

An aspect of this description relates to an integrated circuit. The integrated circuit includes a main switch, wherein the main switch comprises a first high electron mobility transistor (HEMT). The integrated circuit further includes a subcircuit comprising a plurality of second HEMTs, wherein a gate of the main switch is electrically connected to the subcircuit, each of the plurality of second HEMTs is drain-to-gate connected, and adjacent HEMTs of the plurality of second HEMTs are connected in series by a drain-to-source connection. The integrated circuit further includes a third HEMT electrically connected to the gate of the main switch, wherein the third HEMT is drain-to-gate connected, and a drain of the third HEMT is electrically connected to a source of the main switch. The integrated circuit further includes a fourth HEMT electrically connected to the gate of the main switch, wherein the fourth HEMT is drain-to-gate connected. The integrated circuit further includes a fifth HEMT electrically connected to the gate of the main switch, wherein the fifth HEMT is source-to-gate connected, and the fourth HEMT is connected in parallel with the fifth HEMT. In some embodiments, the integrated circuit further includes a sixth HEMT selectively electrically connected to the gate of the main switch, wherein the sixth HEMT is source-to-gate connected, and the sixth HEMT is connected in series with the fourth HEMT. In some embodiments, the integrated circuit further includes a seventh HEMT selectively electrically connected to the gate of the main switch, wherein the seventh HEMT is drain-to-gate connected, and the seventh HEMT is connected in series between the fourth HEMT and the sixth HEMT. In some embodiments, the sixth HEMT is connected in parallel with the fifth HEMT. In some embodiments, the sixth HEMT is connected in series with the fourth HEMT. In some embodiments, the integrated circuit has a breakdown voltage rating ranging from 20 volts (V) to 100V. In some embodiments, the main switch has a breakdown voltage rating ranging from 40V to 1500V. In some embodiments, fingers of each of the plurality of second HEMTs, the third HEMT, the fourth HEMT, and the fifth HEMT are parallel. In some embodiments, the integrated circuit is an all-HEMT integrated circuit. In some embodiments, at least one of the main switch, the plurality of second HEMTs, the third HEMT, the fourth HEMT, or the fifth HEMT comprises gallium nitride (GaN). In some embodiments, the main switch has a threshold voltage of about 2.8 V. In some embodiments, the main switch has a threshold voltage of about 4 V. In some embodiments, the integrated circuit further includes a resistor connected to the gate of the main switch, wherein the resistor is connected in parallel with the plurality of second Hemts. In some embodiments, the integrated circuit further includes a two-dimensional electron gas (2-DEG) resistor selectively electrically connected to the gate of the main switch. In some embodiments, the 2-DEG resistor is connected in series with the fourth HEMT.

An aspect of this description relates to an integrated circuit. The integrated circuit includes an active area having a first region and a second region, wherein fingers in the first region are larger than fingers in the second region. The integrated circuit further includes a drain pad extending continuously across the first region and the second region. The integrated circuit further includes a source pad extending continuously across the first region and the second region. The integrated circuit further includes a region within the second region. The third region includes a main switch, wherein the main switch comprises a first high electron mobility transistor (HEMT). The third region further includes a subcircuit comprising a plurality of second HEMTs, wherein a gate of the main switch is electrically connected to the subcircuit, each of the plurality of second HEMTs is drain-to-gate connected, and adjacent HEMTs of the plurality of second HEMTs are connected in series by a drain-to-source connection. The third region further includes a third HEMT electrically connected to the gate of the main switch, wherein the third HEMT is drain-to-gate connected, and a drain of the third HEMT is electrically connected to a source of the main switch. The third region further includes a fourth HEMT electrically connected to the gate of the main switch, wherein the fourth HEMT is drain-to-gate connected. The third region further includes a fifth HEMT electrically connected to the gate of the main switch, wherein the fifth HEMT is source-to-gate connected, and the fourth HEMT is connected in parallel with the fifth HEMT. In some embodiments, the third region further includes a sixth HEMT selectively electrically connected to the gate of the main switch, wherein the sixth HEMT is source-to-gate connected, and the sixth HEMT is connected in series with the fourth HEMT. In some embodiments, the third region further includes a seventh HEMT selectively electrically connected to the gate of the main switch, wherein the seventh HEMT is drain-to-gate connected, and the seventh HEMT is connected in series between the fourth HEMT and the sixth HEMT. In some embodiments, the source pad is between the third region and the drain pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit comprising:
a main switch, wherein the main switch comprises a first high electron mobility transistor (HEMT);
a subcircuit comprising a plurality of second HEMTs, wherein a gate of the main switch is electrically connected to the subcircuit, each of the plurality of second HEMTs is drain-to-gate connected, and adjacent HEMTs of the plurality of second HEMTs are connected in series by a drain-to-source connection;
a third HEMT electrically connected to the gate of the main switch, wherein the third HEMT is drain-to-gate connected, and a drain of the third HEMT is electrically connected to a source of the main switch;
a fourth HEMT electrically connected to the gate of the main switch, wherein the fourth HEMT is drain-to-gate connected; and
a fifth HEMT electrically connected to the gate of the main switch, wherein the fifth HEMT is source-to-gate connected, and the fourth HEMT is connected in parallel with the fifth HEMT.

2. The integrated circuit according to claim 1, further comprising:
a sixth HEMT selectively electrically connected to the gate of the main switch, wherein the sixth HEMT is source-to-gate connected depletion mode FET, and the sixth HEMT is connected in series with the fourth HEMT.

3. The integrated circuit according to claim 2, further comprising:
a seventh HEMT selectively electrically connected to the gate of the main switch, wherein the seventh HEMT is drain-to-gate connected, and the seventh HEMT is connected in series between the fourth HEMT and the sixth HEMT.

4. The integrated circuit according to claim 2, wherein the sixth HEMT is connected in parallel with the fifth HEMT.

5. The integrated circuit according to claim 2, wherein the sixth HEMT is connected in series with the fourth HEMT.

6. The integrated circuit according to claim 1, wherein the integrated circuit has a breakdown voltage rating ranging from 20 volts (V) to 100V.

7. The integrated circuit according to claim 1, wherein the main switch has a breakdown voltage rating ranging from 40V to 1500V.

8. The integrated circuit according to claim 1, wherein fingers of each of the plurality of second HEMTs, the third HEMT, the fourth HEMT, and the fifth HEMT are parallel.

9. The integrated circuit according to claim 1, wherein the integrated circuit is an all-HEMT integrated circuit.

10. The integrated circuit according to claim 1, wherein at least one of the main switch, the plurality of second HEMTs, the third HEMT, the fourth HEMT, or the fifth HEMT comprises gallium nitride (GaN).

11. The integrated circuit according to claim 1, wherein the main switch has a threshold voltage of about 2.8 V.

12. The integrated circuit according to claim 1, wherein the main switch has a threshold voltage of about 4 V.

13. The integrated circuit according to claim 1, further comprising a resistor connected to the gate of the main switch, wherein the resistor is connected in parallel with the plurality of second HEMTs.

14. The integrated circuit according to claim 1, further comprising a two-dimensional electron gas (2-DEG) resistor selectively electrically connected to the gate of the main switch.

15. The integrated circuit according to claim 14, wherein the 2-DEG resistor is connected in series with the fourth HEMT.

16. The integrated circuit according to claim 1, wherein a number of the plurality of second HEMTs is three.

17. An integrated circuit comprising:
an active area having a first region and a second region, wherein fingers in the first region are larger than fingers in the second region;
a drain pad extending continuously across the first region and the second region;
a source pad extending continuously across the first region and the second region; and
a region within the second region, and the third region comprises:
a main switch, wherein the main switch comprises a first high electron mobility transistor (HEMT);
a subcircuit comprising a plurality of second HEMTs, wherein a gate of the main switch is electrically connected to the subcircuit, each of the plurality of second HEMTs is drain-to-gate connected, and adjacent HEMTs of the plurality of second HEMTs are connected in series by a drain-to-source connection;
a third HEMT electrically connected to the gate of the main switch, wherein the third HEMT is drain-to-gate connected, and a drain of the third HEMT is electrically connected to a source of the main switch;
a fourth HEMT electrically connected to the gate of the main switch, wherein the fourth HEMT is drain-to-gate connected; and
a fifth HEMT electrically connected to the gate of the main switch, wherein the fifth HEMT is source-to-gate connected, and the fourth HEMT is connected in parallel with the fifth HEMT.

18. The integrated circuit according to claim 17, wherein the third region further comprises:
a sixth HEMT selectively electrically connected to the gate of the main switch, wherein the sixth HEMT is source-to-gate connected, and the sixth HEMT is connected in series with the fourth HEMT.

19. The integrated circuit according to claim 18, wherein the third region further comprises:
a seventh HEMT selectively electrically connected to the gate of the main switch, wherein the seventh HEMT is drain-to-gate connected, and the seventh HEMT is connected in series between the fourth HEMT and the sixth HEMT.

20. The integrated circuit according to claim 17, wherein the source pad is between the third region and the drain pad.
